(19) United States
(12) Patent Application Publication
(10) Pub. No.: US 2017/0317259 A1
(43) Pub. Date: Nov. 2, 2017

(54) System, apparatus, and method for increasing the throughput of a three-dimensional printer

(71) Applicants: Peter Hatch, Royal Oak, MI (US); Timothy Trudell, Rochester, MI (US); Alex Hatch, Royal Oak, MI (US)

(72) Inventors: Peter Hatch, Royal Oak, MI (US); Timothy Trudell, Rochester, MI (US); Alex Hatch, Royal Oak, MI (US)

(21) Appl. No.: 14/999,400

(22) Filed: May 2, 2016

(51) Int. Cl. H01L 35/32; B33Y 50/02; B33Y 30/00

(52) U.S. Cl. CPC H01L 35/32; B33Y 30/00; B33Y 50/02

(57) ABSTRACT

A system, apparatus, and method that increases the throughput and output fidelity of a three-dimensional printer by providing a temperature controlled build platform that binds to viscous materials which the three-dimensional printer deposits on the build platform during the fabrication process and subsequently releases the finished product when the build platform is sufficiently cooled. The system provides computer controlled electronic means to modify the temperature gradient of the build platform variably during the build process to assure the quality and fidelity of a printed part produced by the three dimensional printer. The temperature control apparatus includes a set of thermoelectric cells that heat and cool portions of the build plate under software control. The temperature control apparatus also provides conductive materials including a plurality of heat pipes and a plurality of radiative devices that efficiently conduct heat to and from the build plate.

### FIELD OF THE INVENTION

A system that increases the throughput and output fidelity of a three-dimensional printer by providing a temperature controlled multifunctional build platform.

### BACKGROUND OF THE INVENTION

There are a wide variety of three-dimensional printers that rely on a variety of technologies to fabricate products that may include plastic parts, food products, and living tissue. The range of available technologies that three-dimensional printers use include: fused deposition modeling, stereo-lithography, selective laser sintering, selective laser melting, electronic beam melting, laminated object manufacturing as well as other technologies that may come into existence. Three-dimensional printers often include build plates that are used to support a work-in-process while the three-dimensional printer fabricates a desired object.

As an example: A variety of three-dimensional printers produce three-dimensional objects by extruding certain viscous materials. The materials may include thermoplastics; thermoplastic compositions; compounds that are embedded into thermoplastics; amalgams of thermoplastics and embedded compounds; thermoplastics that are doped with powders, dyes, and other substances; along with other materials that may exist or come into existence.

Another example of the technology includes three-dimensional printers that produce processed products from food-stuffs that may be suitable for human consumption. Three-dimensional printers may also be adapted to produce living tissue that may be used to replace living body parts.

Many types of three-dimensional printers rely on build plates to support a work-in-process during the fabrication process of the three-dimensional printer. Build-plates are often passive elements that do not actively contribute to the build process and may create obstacles to efficient utilization of a three-dimensional printer.

As an example of the issues related to the build plate: A three-dimensional printer may produce three-dimensional objects by extruding molten thermoplastic and depositing successive layers of the molten thermoplastic sequentially and orthogonally up from the build plate. The initial layers of molten thermoplastic exiting from the printer's extruder or print head that are applied directly onto the build plate may not adhere to the build plate, and the work-in-process may remain attached to the moving extruder tip of the printer and slide the work-in-process around the build plate causing misalignment of the successive layers of molten thermoplastic resulting in failure of the finished product.

During the build process, a work-in-process object may also warp, curl, or creep due to non-uniform cooling of the molten thermoplastic of the object being printed. As the extruded molten thermoplastic cools and hardens, it shrinks slightly. When a the thermoplastic printed object does not shrink uniformly as it cools and sets, the resulting finished printed part may be warped and unusable. Damage to the finished part is commonly evidenced by corners of the printed part lifting off of the build plate or platform.

Upon completion of the build cycle, another problem may arise when removing the finished object from the build plate. It may be difficult to efficiently remove the finished object from the build plate of the 3-D printer because the printed object may remain adhered to the build plate often requiring the use of a knife or scraper to remove the printed object, which is both time consuming and hazardous to the finished product, the build plate, and the printer operator.

Three-dimensional printers may also provide multiple print heads utilizing multiple materials that result in more complex printed objects having thermal properties that vary throughout the finished object. In some instances, the fine temperature gradient management of the build plate is insufficient resulting in nonconforming products.

Build plates are typically composed of metal, plastic or glass that are not usually an effective build surface for a printed object and require enhancements to function efficiently. Modifications to enhance the performance of metal build surfaces include the application of polymide tape, blue painter's tape or other manually applied materials that the molten thermoplastic will adhere to but still permit manual removal of the finished product. Glass build plates may be enhanced in the same manner as metal build plates by the use of diluted polyvinyl acetate glue or certain hair sprays that may be dissolved when the printed product is completed. Applying enhancemens to the build plate is a manual process that requires time consuming effort and often prevents the use of three dimensional printers in automated processes. Eliminating the need for enhancements would significantly improve the efficiency of a three-dimensional printer and expand its utility to more automated processes.

Controlling the build plate temperature aids in addressing product warping. A heated build platform improves printing quality by helping to prevent warping that may occur as the molten thermoplastic cools during the build process. A heated build plate keeps the printed object warm during the printing process and permits more uniform shrinking of the thermoplastic product as it cools below its melting point. Heated beds usually yield higher quality finished builds with materials such as ABS and PLA. A heated build plate may also allow 3-D printer operators to print objects without rafts. Existing build plates, however, are designed to achieve a uniform temperature across the surface of the build plate, which may not produce the optimum quality build possible. The composition and geometry of a work in process may require a varying temperature gradient across the build plate.

Heating a build plate may also cause the build plate itself to warp damaging or reducing the quality of the completed part.

Flexible synthetic build plates have also been developed that provide a medium that adheres to molten thermoplastic. The synthetic build plate is manually inserted onto the standard build plate of a three-dimensional printer before the print process is started. After the printing process is finished, the thermoplastic part is completed and passively cools to an appropriate temperature. The synthetic build plate with the completed part attached is removed from the printer. The printer operator manually bends, twists, or manipulates the synthetic build plate releasing the thermoplastic part from the surface of the synthetic build plate. Manual intervention in the process is time consuming and prevents full automation of part fabrication.

For food production, the build plate temperature may need to be substantially reduced below the ambient temperature along with other build plate temperature adjustments to aid in efficiently forming the completed product. In the case of living tissue, the build pate may need to remain within a very specific range of temperatures throughout the build process. In other instances, the build plate temperature may need to remain within certain ranges in order for a product to properly set.

The examples above are only for illustrative purposes and are not intended to be limiting. These and other situations that exist and may come into existence show how the build plate is an obstacle to increasing the throughput and output fidelity of three-dimensional printers.

The present invention overcomes the limitations of existing build plates by providing a system that controls the temperature of an included multifunctional build plate during and after the fabrication process of a three-dimensional printer.

### SUMMARY

A system, apparatus, and method for controlling the temperature of a build platform to enhance the throughput and output fidelity of a three-dimensional printer. One aspect of the invention provides a multifunctional build platform having a first planar surface and a second planar surface on the opposite side of the first surface of the build platform; a plurality of thermoelectric cell attached to the second surface of the build platform and in electronic communication with a temperature controller; a plurality of temperature sensors connected to the build platform and in electronic communication with a temperature controller; a thermal conduction apparatus ; and a temperature controller having means for accepting electronic temperature signals from the temperature sensors, processing the temperature signals and transmitting signals to the thermoelectric cells to control the temperature of the build platform. The mutifunctional build platform adheres to extruded viscous raw materials that a three-dimensional printer applies to the build platform to fabricate finished products. After the build is completed, the system reduces the temperature of the build platform at a controlled rate. Upon reaching the appropriate temperature, the completed object releases itself from the build platform. In other aspects of the invention, the system provides point by point control of the build platform temperature throughout the build process to fulfill the heating and cooling requirements that are specific to the type of product being produced by the three-dimensional printer.

The system is installed in a three-dimensional printer and replaces the standard build plate of a three-dimensional printer. When an operator initiates a build process in the printer, the electronic controllers of the invention heat or cool the build platform to a predetermined temperature and controls the thermal gradient of the build platform surface during the build process. Upon completion of the build, the electronic controls of the system, modify the temperature of the build platform in accordance with a computer algorithm releasing the finished part.

To further enhance the throughput and overall safe efficient operation of three-dimensional printers, the system may include routines for preemptive detection and diagnosis of thermoelectric cell performance variances and build platform temperatures that could cause failure of the build process or the finished part. The routines may include a built in self-test that is completed before the three-dimensional printer initiates fabrication of the product. Once fabrication starts, another routine may dynamically monitor thermoelectric cell performance within the scope of external environmental factors, the performance limits of the thermoelectric cells, and the thermal properties of the raw materials that the three-dimensional printer uses to fabricate products. Upon detection of variances that exceed the performance parameters of a specific fabrication job, the system notifies the operator and initiates prophylactic action to protect the three-dimensional printer, the work-in-process, and the printer operator from physical and chemical dangers arising from improper thermal gradients. The electronics and computer controls of the system also compensate for variations in individual thermoelectric cell performance that may arise due to pre-existing variances caused during manufacturing of the thermoelectric cells or resulting from aging or use of the cells in the system for heating and cooling.

The system provides a plurality of thermoelectric cells that heat and cool the build platform in response to electronic power and signals provided by thermal controllers. Each thermoelectric cell may be controlled separately and independently from the other thermoelectric cells to permit the temperature of each predefined section of the build platform to be determined by a corresponding thermoelectric device. By providing control of the temperature of each zone or section of the build platform, the printer operator has greater control over the quality and fidelity of the finished part produced by the printer.

Heat transfer to and from the build plate is facilitated by a thermal conduction apparatus that connects to a lower side of the thermoelectric cells and the exterior of the three-dimensional printer. The apparatus provides a base plate that has a first planar surface that securely attaches to the thermoelectric devices on a side of the thermoelectric devices that is on the opposite side of the thermoelectric device to where the thermoelectric devices attach to the build plate. The element is made of metal such as copper or aluminum or another rigid material that provides sufficient thermal conductivity to efficiently transfer heat to and from the thermoelectric devices. There may be at least one water block cooler that uses water or other liquid or a plurality of heat pipes securely attached to a second side of the element on the side opposite to where the thermoelectric devices are attached. The heat pipes connect the base plate to a plurality of radiative elements coupled with the external structure of the three-dimensional printer. The heat pipes may extend out horizontally in a radial pattern or other appropriate geometric pattern from the conductive element to the periphery of the three-dimensional printer.

The radiative elements are semi-tubular and extend vertically upward from the periphery of the base plate a predefined distance. The radiative elements are made of metal such as copper or aluminum or another rigid material that provides sufficient thermal conductivity to efficiently transfer heat to and from the conductive element. The radiative elements provide a means to efficiently transfer heat to and from the base plate of the invention to the external environment surrounding the three-dimensional printer. The system provides electronic devices and computer software means to monitor the temperature of the build plate and to provide power to the thermoelectric devices that are used to heat and cool the build plate.

### BRIEF DESCRIPTION OF THE DRAWINGS

These and other objects, features, and advantages of the present invention will become apparent from the following detailed description and the appended drawings in which:

FIG. 1 illustrates a side perspective view of an embodiment of the present invention

FIG. 2 illustrates the prior art, which is a side view of the three-dimensional printer without the physical components of the present invention.

FIG. 3 illustrates a side view of a three-dimensional printer with an embodiment of the present invention shown in FIG. 1 installed in the three dimensional printer.

FIG. 4 illustrates a side view of an embodiment of the present invention shown in FIG. 1.

FIG. 5 illustrates an exploded side perspective view of the physical components of an aspect of the invention shown in FIG. 1 showing a build platform, thermoelectric cells, a base plate, heat pipes, and radiative elements that are components of an aspect of the invention as shown in FIG. 1.

FIG. 6 illustrates an inverted exploded side perspective view of the physical components of an aspect of the invention shown in FIG. 1 showing a heat pipes, radiative elements, a base plate, thermoelectric cells, and a build platform that are components of an aspect of the invention as shown in FIG. 1.

FIG. 7 illustrates a top view of a build platform, which is a component of an embodiment of the invention shown in FIG. 1.

FIG. 8. illustrates a top view of an alternative build platform, which is a component of an alternate embodiment of the invention shown in FIG. 1.

FIG. 9 illustrates a bottom view of a build platform for an embodiment of the invention shown in FIG. 1 showing a possible electric circuit bonded to or etched on the bottom surface of the build plate and adapted for installation of thermoelectric cells that are a component of the invention.

FIG. 10 illustrates a bottom view of the build plate shown in FIG. 9 coupled with thermoelectric cells that are connected to the electric circuit on the bottom surface of the build plate and are a component of the invention shown in FIG. 1.

FIG. 11 illustrates a schematic representation of an aspect of the invention shown in FIG. 1.

FIG. 12 illustrates a flowchart representation for an aspect of the invention shown in FIG. 1 showing the system process for controlling a uniform thermal gradient across the surface of the build plate component of the invention.

FIG. 13 illustrates a bottom view of an alternative build plate coupled with thermoelectric cells connected to an alternative circuit for an alternative embodiment of the invention shown in FIG. 1 that are a component of the invention.

FIG. 14 illustrates a bottom view of an alternative build plate for an alternative embodiment of the invention shown in FIG. 1 showing a possible electric circuit adapted to be coupled with thermoelectric cells that are a component of the invention.

FIG. 15 illustrates is a bottom view of an alternative build plate for an alternative embodiment of the invention shown in FIG. 1 showing the alternative build plate coupled with thermoelectric devices that are a component of the invention.

FIG. 16 illustrates a schematic representation of an alternative aspect of the invention shown in FIG. 1.

FIG. 17 illustrates a flowchart representation for an aspect of an alternative embodiment of the invention shown in FIG. 1 made in conformance with the schematic diagram of FIG. 16 showing the system process for controlling a variable thermal gradient of the surface of a build plate component of the system.

### DETAILED DESCRIPTION OF THE INVENTION

The embodiments of the invention disclosed in this description are merely exemplary of the invention that may be embodied in various and alternative forms. The drawings and figures included with this description are not necessarily to scale, and features may be exaggerated or minimized to illustrate details of particular components. Specific structural and functional details disclosed should be interpreted merely as a representative basis to variously employ the present invention and should not to be interpreted as limiting the invention.

The embodiments of the present disclosure generally provide for a plurality of circuits and/or electrical devices. All references to the circuits or electrical devices and the functionality provided by each, are not intended to be limited to encompassing only what is illustrated and described herein. While particular labels may be assigned to the various circuits or other electrical devices disclosed, such labels are not intended to limit the scope of operation for the circuits and/or the other electrical devices. Such circuits and/or other electrical devices may be combined with each other and/or separated in any manner based on the particular type of electrical implementation that is desired. It is recognized that any circuit and/or other electrical device disclosed herein may include any number of microprocessors, integrated circuits, memory devices (e.g., FLASH, RAM, ROM, EPROM, EEPROM, or other suitable variants thereof) and software which co-act with one another to perform operation(s) disclosed herein.

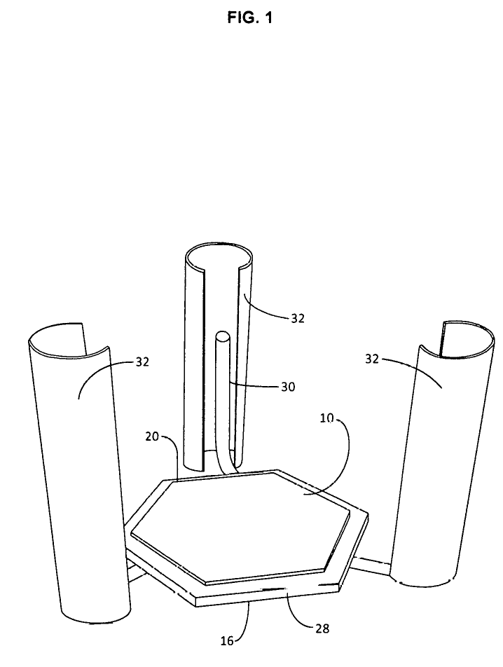

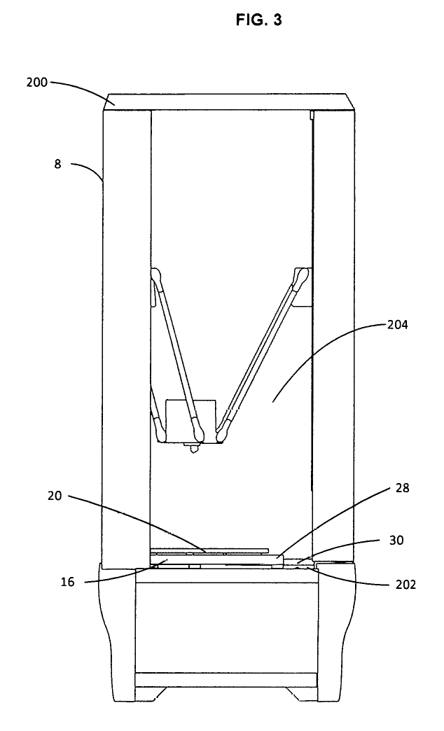

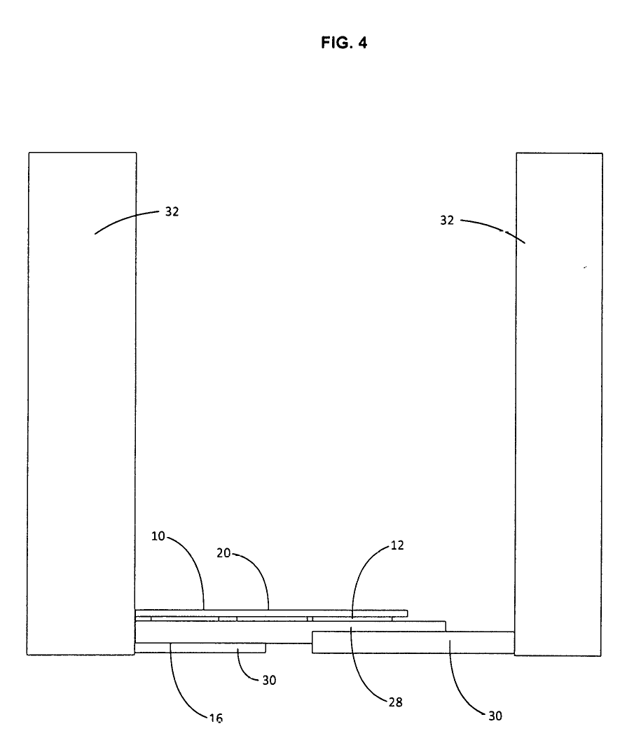

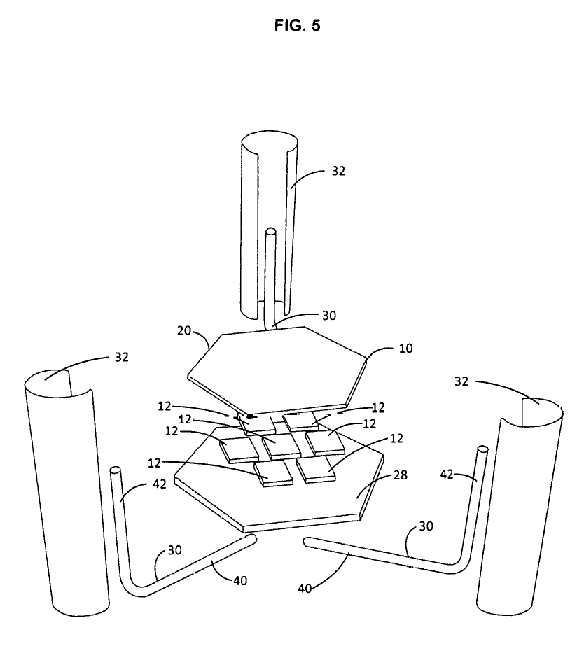

As shown in FIG. 1 and FIG. 3, an aspect of the invention provides a system 8 for controlling the temperature of a build plate to enhance the throughput and output fidelity of a three-dimensional printer 200. As shown in FIG. 5, the system provides a multifunctional build platform 10, a plurality of thermoelectric cells 12, a plurality of temperature sensors, a thermal conduction apparatus 16, a printed circuit board 18 shown schematically in FIG. 11 having electronic components, and a computer that executes algorithms to control the temperature of the build platform.

The system may produce a uniform or variable thermal gradient across the build platform 10 that ranges in variability from a substantially uniform temperature gradient across the build platform to a temperature gradient that varies point wise from point to point across the surface plane of the build platform . The variability of the temperature gradient is dependent on the number of jointly or independently computer controlled thermoelectric cells 12 shown in FIG. 5 coupled between the build platform 10 and a thermal conduction apparatus 16. The thermoelectric cells 12 are under joint or independent control of the computer algorithms that and electronic control devices on the printed circuit board 18 shown schematically in FIG. 11.

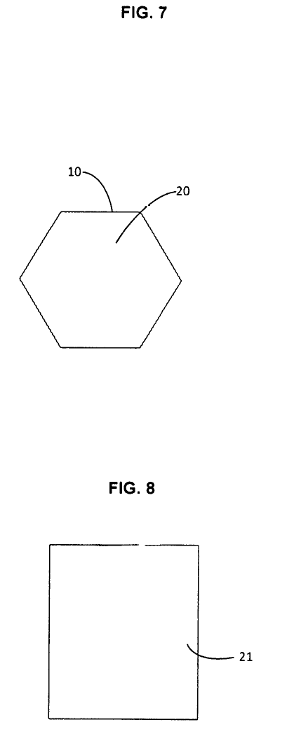

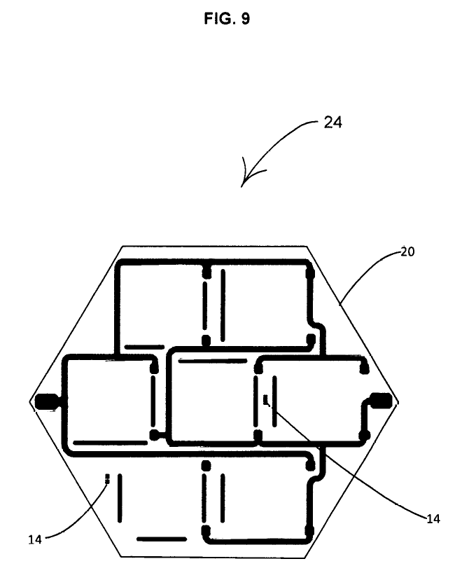

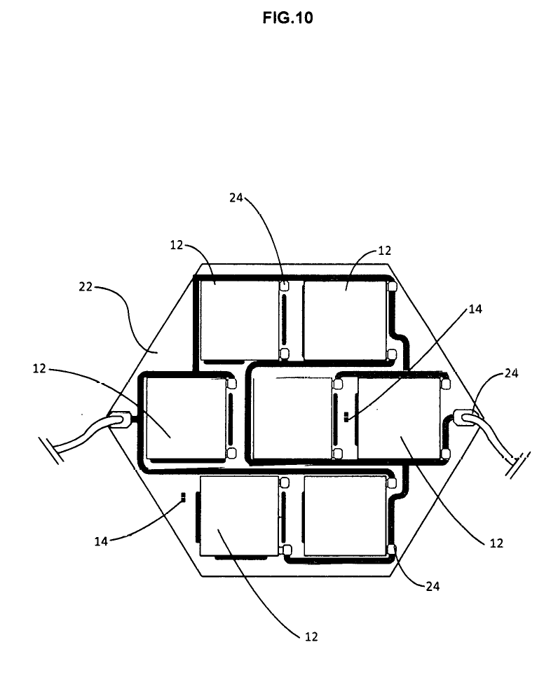

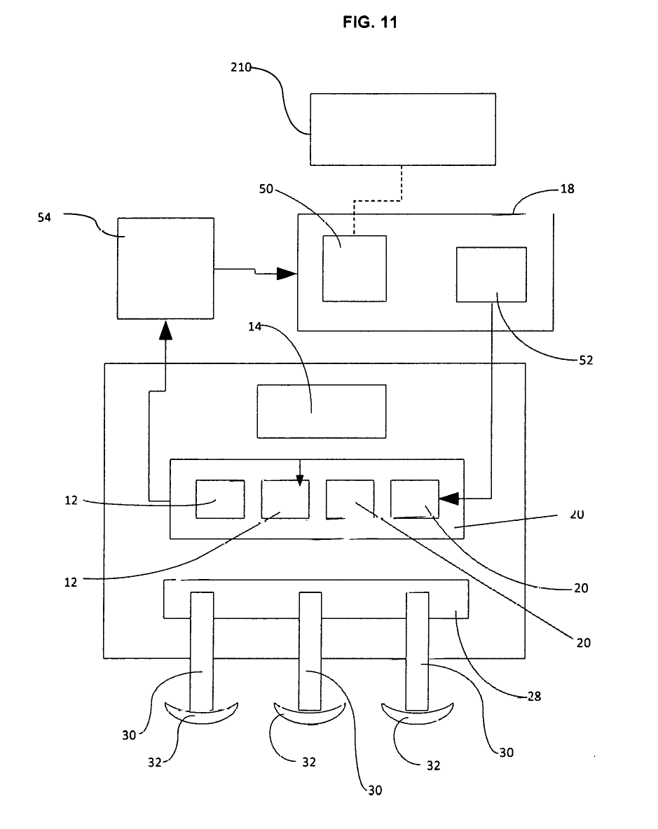

The multifunctional build platform 10 is multifunctional in that the build platform as shown in FIG. 7 or FIG. 8 provides a build plate 20, 21 to support a work-in-process during the production cycle of a three dimensional printer; provides a substrate for a printed circuit 22 as shown in FIG. 9 that supplies electrical power as show in FIG. 10 to the thermoelectric cells 12 and electronic signals to temperature controllers; and provides a thermal path that conducts heat to and from the work-in-process in accordance with a thermal gradient or thermal profile that extends across the build platform under system provided software control.

As shown in FIG. 7 and FIG. 9, the build platform 10 is a substantially rigid planar material that may have any appropriate geometric dimensions adapted to fit horizontally across the bottom of the build chamber of a three-dimensional printer. The build platform 10 may be made from compositions of ceramic compounds that may include high thermal conductivity compounds such as aluminum nitride, aluminum oxide, or boron nitride; or any other rigid material that remains dimensionally stable without warping or other significant dimensional alteration over the temperature range that a work-in-process may experience while being fabricated by a three-dimensional printer and of sufficient thickness to endure substantial thermal stress resulting from a variable thermal gradient imposed on the build platform by the print head of a three dimensional printer, the molten heat of a work-in process objects, and the heating and cooling effect of the thermoelectric cells or other temperature modification devices . The material comprising the build platform 10 is thermally conductive while providing sufficient electronic isolation of the various electronic components attached to the electric circuits 24 printed on the second surface of the build platform as shown in FIG. 9 to allow each attached electronic component to properly function in response to electronic signals communicated through the printed circuits and the electric current supplied through the electric circuits.

In one aspect of the invention, the build platform 10 is planar and of an appropriate geometric configuration adapted to fit horizontally across the bottom of a build chamber of a three-dimensional printer 200. As shown in FIG. 3 the build platform 10 provides a first surface that functions as a build plate 20 for the printer and provides a second surface 22 on the opposite side the build plate from the first surface that provides additional functioning as described below. The first surface or build plate 20 is adapted to accept extruded viscous raw materials exiting from the print head of a three-dimensional printer 200. The print head applies the extruded viscous raw materials in a predefined pattern creating a work-in-process by building up a part in a vertical direction orthogonal to the build plate 20, which is adapted to adhere to the viscous raw materials that are extruded from the print head and to subsequently release the adhered materials when the work-in-process is fabricated into a finished products and the temperature of the build platform and the finished product is sufficiently modified, which may occur at a predefined rate. .

As shown in FIG. 9, the second surface 22 of the build platform 10 is substantially planar and may have a printed circuit bonded to the second surface or etched directly unto the second surface , The electric circuit 24 transmits electric power to the thermoelectric cells and transmits and communicates electrical signals from temperature sensors 14 to the circuit board under the control of the computer algorithms. The temperature sensors 14 may be thermistors, thermocouples or other electronic sensors adapted to communicate temperatures electronically to the electronic controls on the printed circuit board 18 that monitor the temperature of the build plate 20 and provides power to the thermoelectric cells 12 through the conductive traces of the electric circuit 24 on the second surface 22 of the build plate 20 in response to the specific requirements for a particular product being fabricated by the three-dimensional printer. The temperature sensors 14 are coupled to the second surface of the build platform by solder or other appropriate means and are connected to the thermal controller on the printed-circuit-board-A by wires or other appropriate means to permit electronic communication between the temperature sensors and the thermal controller. The system may provide a sufficient number of temperature sensors to provide redundancy.

As shown in FIG. 10, each thermoelectric cell 12 is securely coupled with to and appropriately oriented to the electric circuit 24 provided on the second surface 22 of the build platform 10 to permit each thermoelectric cell 12 to heat or cool the build plate 20 as directed by the thermal controllers associated with the printed circuit board 18. Each thermoelectric cell 12 is attached to the electric circuit 24 associated with the second surface of the build platform by solder or other appropriate means for the system to provide sufficient electric current to power the thermoelectric cells as necessary to maintain or modify the predetermined thermal gradient of the build plate.

The thermoelectric cells 12 may be Peltier devices or other thermoelectric devices that use appropriately biased and powered electric current to heat and cool the build platform 20. The thermoelectric cells 12 are rigidly attached to the electric circuit 24 associated with the second surface 22 of the build plate and the electric leads of the thermoelectric cells 12 are soldered or otherwise connected to the printed circuit associated with the second surface of the build platform to provide electric current to the thermoelectric cells 12 under system control.

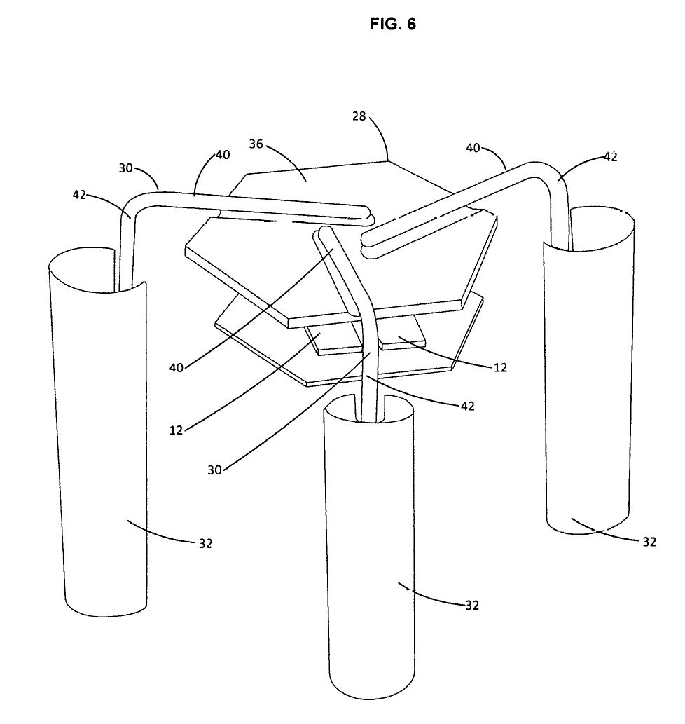

In one aspect of the invention, as shown in FIG. 3, the thermal conduction apparatus 16 transfers heat to and from the environment surrounding the exterior of the three dimensional printer and the thermoelectric cells 12 connected to the build plate 20. As shown in FIG. 5 and FIG. 6, the thermal conduction apparatus 16 may provide a base plate 28 that is a substantially rigid planar element, at least one heat pipe 30 that transfer heat to and from the base plate 28, and at least one radiative element 32 that conducts heat to and from the heat pipes 30 to the exterior environment surrounding the three-dimensional printer 200.

The base plate 28 of the thermal conduction apparatus 16 may be a suitable thermal conductor that may be metal such as copper or aluminum or any other substantially rigid thermally conductive material that will aid in efficiently transferring heat between the thermoelectric cells 12 and the heat pipes 30. As shown in FIG. 1, the base plate 28 is a substantially planar element having appropriate geometric dimensions that may exceed the dimensions of the build plate but not exceed the horizontal limits of the build cavity 204 of the printer. As shown in FIG. 5 and FIG. 6, the base plate 28 provides a first surface 34 and a second surface 36 and is located in the build chamber 202 of the printer below the build platform 10, and as shown in FIG. 3, oriented horizontally with respect to the upright position of the printer 200. The first surface 34 of the base plate is a substantially planar element rigidly attached to the thermoelectric cells on the lower side of the thermoelectric cells opposite to the side where the thermoelectric devices attach to the circuit 24 on build platform 10. The second surface 36 of the base plate is substantially planar and may provide impressions or elongated indentations that extend radially out from the center of the second surface to the periphery of the base plate that are adapted to be coupled with the heat pipes 30.

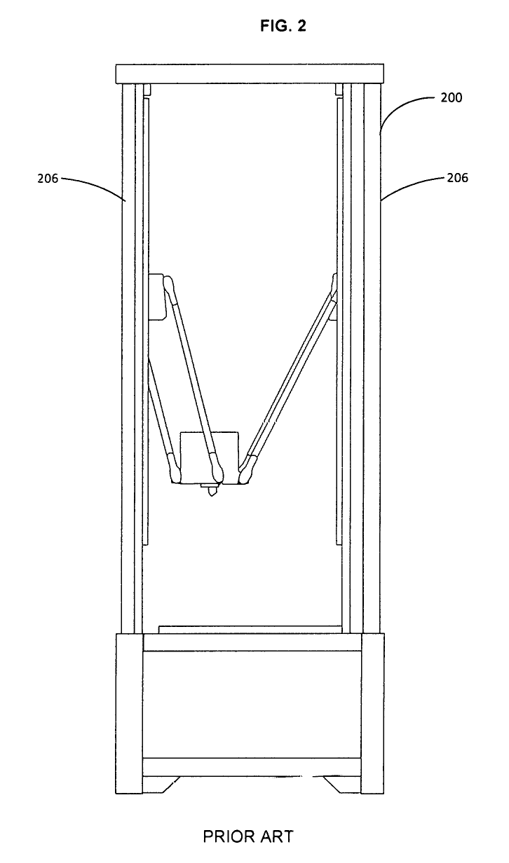

As shown in FIG. 5 and FIG. 6, the heat pipes 30 may be L shaped or any appropriate geometric configuration of appropriate dimensions and having a first linear tubular element 40 and a second linear tubular element 42 connected to and having an appropriate geometrical orientation that may be orthogonal to the first element 40 or oriented at any appropriate angle to accommodate the various structural characteristics of three dimensional printers. The first linear tubular element 40 of each heat pipe 30 is securely coupled to the second surface 36 within the impressions or elongated impressions of the base plate of the thermal conduction apparatus. The first linear tubular elements 40 of the heat pipes 30 may arranged in a substantially radial or other suitable pattern on the second surface 36 of the base plate 28 and extend outward from the geometric center of the second surface 36 a predefined distance past the horizontal periphery of the base plate 28. The second linear tubular element 42 of each heat pipe extends from the first linear tubular element in an appropriate geometrical relationship to the first tubular element beyond the periphery of the base plate and may extend vertically upward and orthogonally away from the base plate 28 or otherwise extend in an appropriate geometric relationship to the base plate. The second linear tubular element 42 of each heat pipe 30 is securely attached to a radiative element 32 that may be securely attached to the exterior frame 206 as shown in FIG. 2, of the three-dimensional printer.

Each radiative element 32 may be an extended semi-tubular rigid element composed of thermally conductive material having a predefined diameter and securely attached to the exterior peripheral structural frame 206 of the three-dimensional printer, as shown in FIG. 3, orthogonally oriented to the build plate 20 and extending vertically upward from the bottom of the three dimensional printer a predefined distance from the first surface of the base plate 28.

In another aspect of the invention, the thermal conduction apparatus may provide at least one water block cooler that uses water or other liquids for heat transfer attached to the second surface of the base plate to provide cooling for the thermoelectric cells.

As shown schematically in FIG. 11, the system provides a printed-circuit-board-A 18 comprised of various electronic components. The electronic components may include a thermal controller 50 and an H-bridge 52, which may be a transistor or H bridge circuit connected to and controlled by appropriate electronic circuitry on the printed circuit board. 18. The printed circuit board 18 receives sufficient electric current from an electronic power supply 54 to power the electronic devices and the thermoelectric cells 12 coupled with the build plate 20. The thermal controller 50 may be comprised of appropriate electronic components and is in electronic communication with a computer 210, the temperature sensors 14 coupled to the build plate 20, and the H-bridge 52. The thermal controller 50 accepts control signals from the computer 210 and accepts electronic temperature reading signals from the temperature sensors 14. The thermal controller 26 transmits electronic temperature signals to the computer 210 and communicates electronically with the H-bridge 52 to provide appropriately biased current to the thermoelectric cells 12 coupled to the build platform 10.

A plurality of temperature sensors 14 are positioned proximate to the thermoelectric cells 12 and electronically communicate the temperature of the build plate 20 to the thermal controller 50 on the printed-circuit-board-A 18. Each temperature sensor 14 transmits a signal to the thermal controller 26 that indicates the temperature of the build plate 20 proximate to the immediate location of the temperature sensor 14. The thermal controller 50 determines whether the temperature of build plate 20 at the location of each temperature sensor 14 is greater or less than a predetermined temperature threshold provided by a computer algorithm.

In one aspect of the invention, during the build phase If the temperature of the build plate 20 at a location proximate to a particular temperature sensor 14 is less than the temperature threshold, then the controller determines that it may be necessary to energize the thermoelectric cells 12 associated with the respective temperature sensors 14 to heat the location on the build plate 20 proximate to the associated temperature sensor.

After the build phase, the system cools the build plate 20 by energizing the thermoelectric components at a current that is biased at a reverse polarity of the current applied to heat the build plate during the build phase. Each temperature sensor 14 transmits a signal to the thermal controller 26 indicating the temperature proximate to the respective temperature sensor 14. The thermal controller 26 determines If the temperature of the build plate 20 at a location proximate to a particular temperature sensor 14 is greater than a temperature threshold associated with the particular temperature sensor, then the thermal controller 26 determines that it may be necessary to energize the thermoelectric cells 12 associated with the respective temperature sensors to cool the location on the build plate 20 proximate to the associated temperature sensor 14.

In some aspects of the invention, the system algorithm relies of differences between the thermal coefficient of expansion for the work-in-process in comparison to the thermal coefficient of expansion of the materials comprising the build plate. The system uses the differences in the expansion rates of the various materials as compared to the thermal expansion rate of the build plate 20 to cause the build plate to release the finished product resulting from the build cycle of a three dimensional printer at the appropriate temperature gradient.

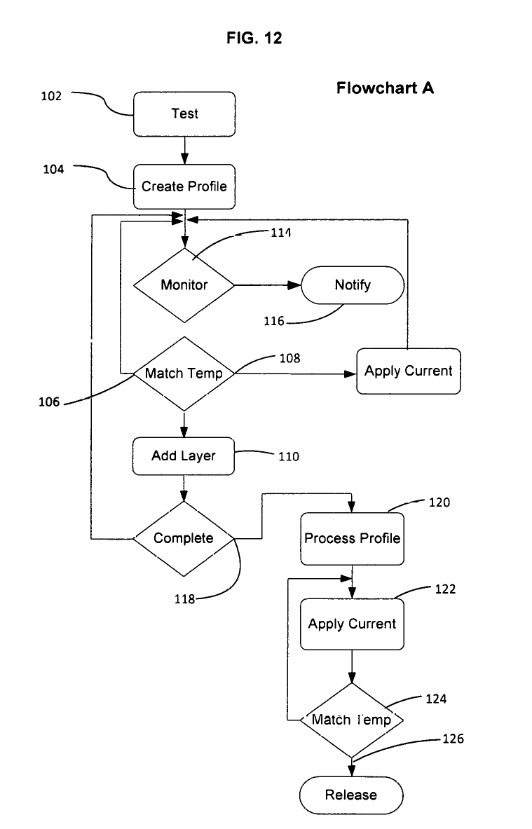

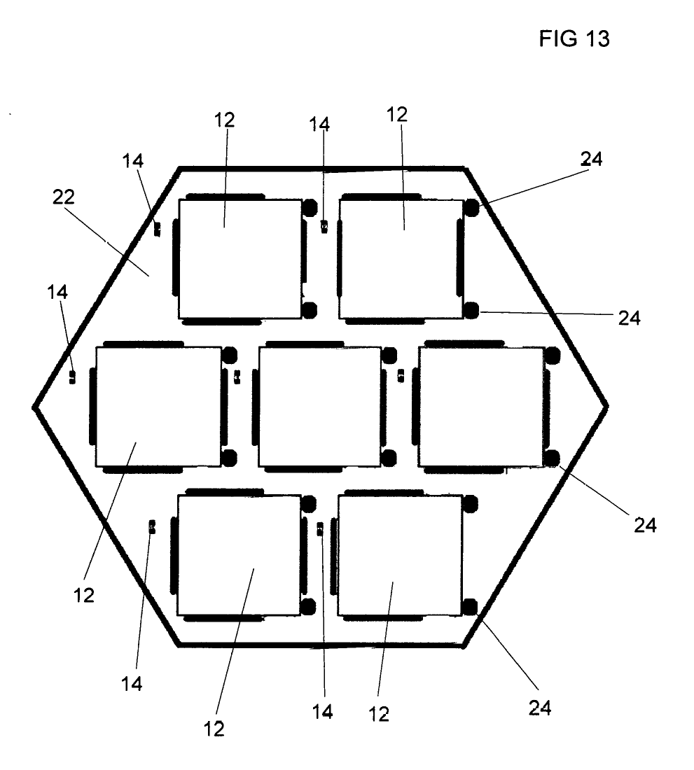

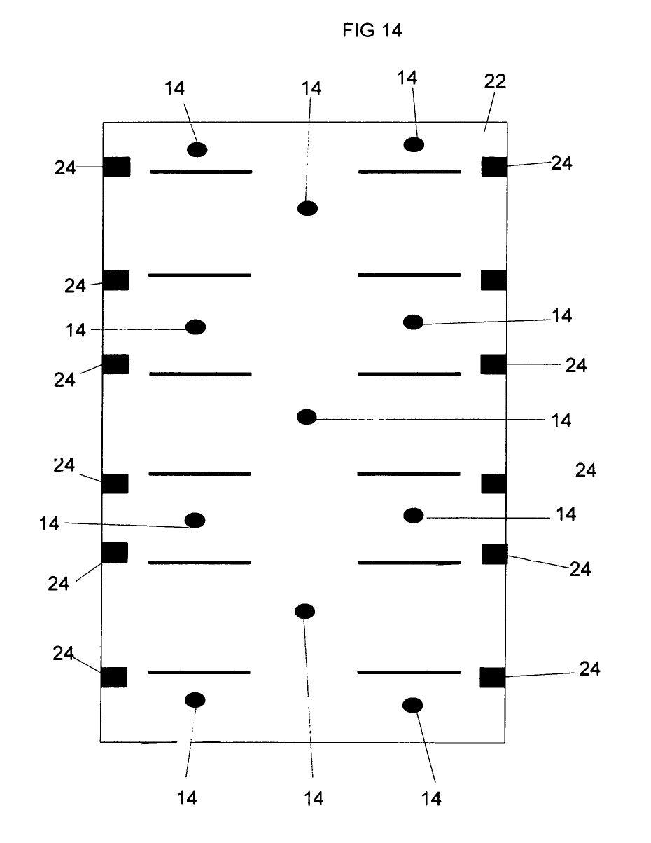

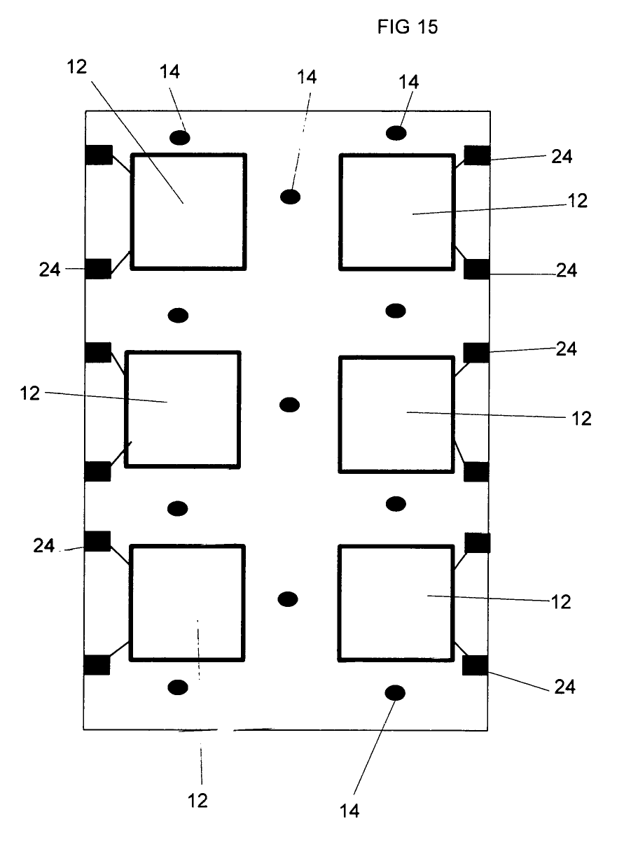

In one aspect of the invention as shown in FIG. 12, flowchart-A 100 schematically illustrates how the system uses a uniform temperature profile to control the temperature of the build plate and how the present system is integrated into the build process of a three-dimensional printer. Before initiation of the build, the system performs a self test 102 to determine if the electronic components and the thermoelectric cells of the system function according to a set of predetermined standards. Upon successful completion of the self test, a file having the temperature profile for the build process and the cooling cycle is input into a computer controlling the three-dimensional printer 104. The computer uses data from the file and an appropriate algorithm based on the physical and chemical properties of the raw materials and environmental factors that may include the ambient temperature and humidity to create a thermal profile or gradient for the build plate 104. The system reads the temperatures of the designated locations on the build plate and compares the respective temperatures to the desired thermal gradient 106. If a variation exists 108, the computer algorithm determines the electric power bias and level of current needed to achieve the desired temperature for each corresponding location on the build plate, and the system electronically communicates the polarity bias and current to the controller for each thermoelectric cell. When the correct temperature gradient is achieved, printing is initiated 110. The system monitors the temperature of the build plate as each layer of printing is completed and electronically communicates the polarity bias and current level needed to the controller for each thermoelectric cell to adjust the temperature as needed to maintain the temperature profile of the build plate during the build process 112.

During the build process, the system dynamically monitors the electronic and thermal performance of the system and compares the performance data to a set of predetermined parameters 114, and communicates electronically to the printer and printer operator 116 if the build process should halt or if any remedial action may be taken to prevent a process failure and to protect the safety of the operator, the printer, and the surrounding environment.

When the three dimensional printer 200 has completed fabricating the work-in-process to produce the intended finished product 118, the system initiates a cooling process 120. The thermal controller compares the temperature at each polling location on the build plate and compares the temperatures to the target values in the file corresponding to each temperature sensor location on the build plate. An algorithm calculates the polarity bias and level of current needed for each thermoelectric cell to cool the build plate in accordance with the cool down temperature gradient of the build plate 122. The system communicates the polarity bias and the current values to the thermal controllers for each thermoelectric cell 124. The system sequentially polls each mapped location of the build plate. The system repeats the procedure until the temperature of the build plate equals a calculated value and the finished part releases from the build plate and the process ends 126.

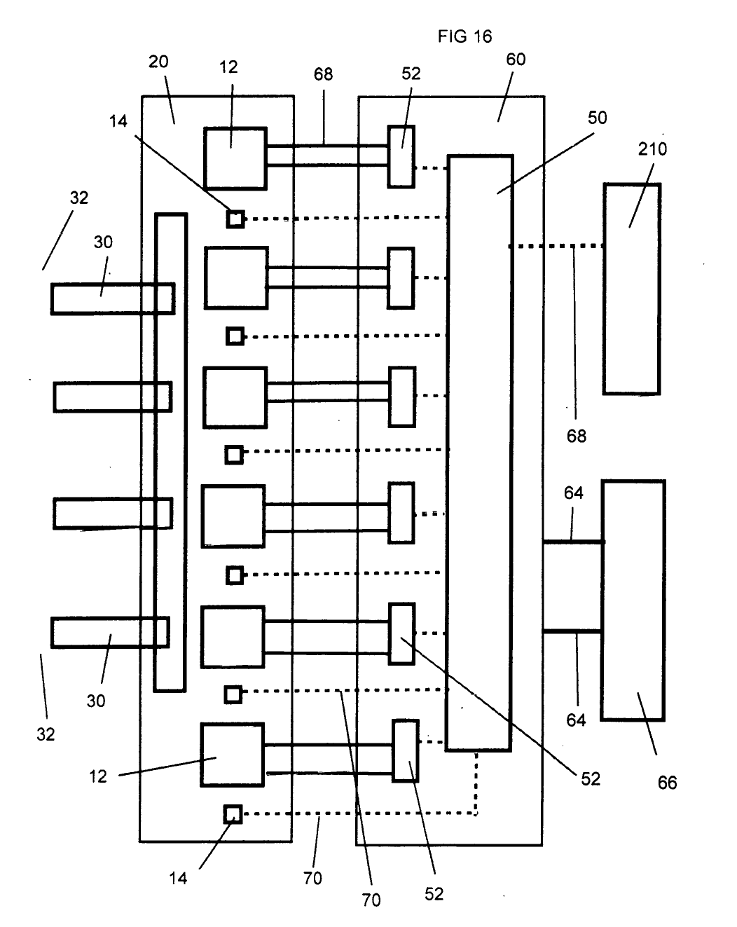

In an alternative embodiment, as shown schematically in FIG. 16, the system provides a printed-circuit-board-B 60 comprised of various electronic components. The electronic components may include a plurality of thermal controllers 50 and a plurality of H-bridges 52, which may be transistors or H bridge circuits. The printed-circuit-board-B 60 receives sufficient electric current 64 from a provided power supply 66 to power the thermal controllers 50 and the H-bridges 52 attached to the printed-circuit-board-B 60 along with the thermoelectric cells 12 coupled with the second surface 22 of the build platform 10. Each thermal controller 50 is comprised of appropriate electronic circuitry and is in electronic communication with a computer 210, one or more temperature sensors 14 coupled to the build platform 10, and an associated H-bridge 52. Each thermal controller 50 accepts control signals 68 from the computer and accepts temperature readings from associated temperature sensors 14. Each thermal controller 50 sends temperature signals to the computer 210 and signals an associated H-bridge 52 to provide appropriately biased current to the associated thermoelectric cells 12 coupled to the build platform 10.

One or more temperature sensors 14 are positioned on the second surface 22 of the build platform 10 proximate to the thermoelectric cells 12 and electronically communicates 70 the temperature of the build platform to the thermal controller 50 associated with the respective H-bridge 52 coupled with printed-circuit-board-B 60. Each temperature sensor 14 transmits a signal 70 to an associated thermal controller 50 that indicates the temperature of the build platform 10 proximate to the immediate location of the respective temperature sensor 14. The thermal controller 50 determines whether the temperature of build platform at the location of each temperature sensor 14 is greater or less than a temperature threshold.

During the build phase of the three dimensional printer, if the temperature of the build plate at a location proximate to a particular temperature sensor 14 is not within the range of a predetermined temperature threshold, then the respective thermal controller determines that it may be necessary to energize the thermoelectric cells 12 associated with the respective temperature sensor 14 with the appropriately biased electric current to heat or cool the location on the build build platform 10 proximate to the associated temperature sensor 14.

After the build phase, the system modifies the temperature of the build platform 10 by energizing the thermoelectric cells 12 at a current that is at reverse polarity of the current applied to heat the build platform 10 during the build phase. Each temperature sensor 14 transmits a signal to an associated thermal controller 50 indicating the temperature proximate to the respective temperature sensor 14. The thermal controller 50 determines If the temperature of the build platform 10 at a location proximate to a particular temperature sensor 14 is greater than than a temperature threshold associated with the particular temperature sensor 14, then the thermal controller 50 determines that it may be necessary to energize the thermoelectric cells 12 associated with the respective temperature sensors 14 to cool the location on the build build platform 10 proximate to the associated temperature sensor 14.

In some aspects of the invention, the system relies of differences between the thermal coefficient of expansion for the work-in-process in comparison to the thermal coefficient of expansion of the materials comprising the build platform 10. The system uses the differences in the expansion rates of the various materials to cause the build plate 20 to release the work-in-process at the appropriate temperature gradient.

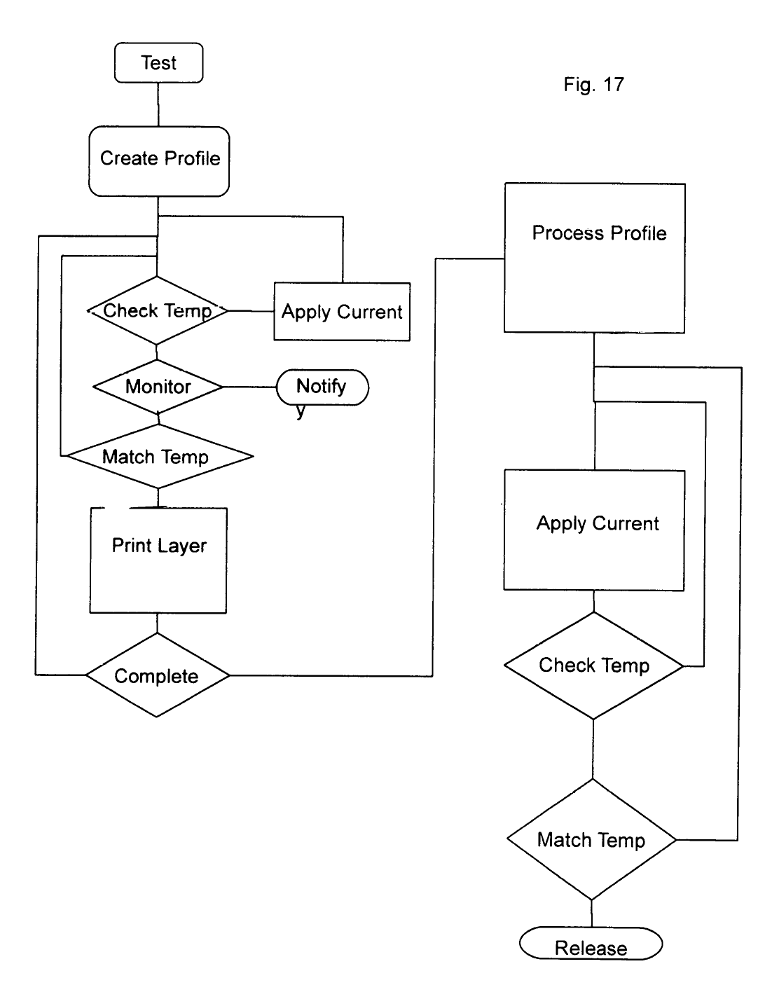

In one aspect of the invention, as shown in FIG. 17, flowchart-B 80 illustrates how the system controls the build plate temperature and illustrates how the temperature control of the the invented system is integrated into the build process of a three-dimensional printer. Before initiation of the build, the system performs a self test 150 to determine if the electronic components and the thermoelectric cells of the system function according to a set of predetermined standards. Upon successful completion of the self-test, a file having the temperature profile for the build process and the cooling cycle is input into a computer controlling the three-dimensional printer 152. The computer uses data from the file and an appropriate algorithm based on the physical and chemical properties of the raw materials and environmental factors that may include the ambient temperature and humidity to create a thermal profile or gradient for the build plate 154. The system reads the temperatures from the temperature sensors at designated locations on the build plate and compares the respective temperatures to the desired thermal gradient 156. If a temperature variation exists 158, a computer algorithm determines the electric power bias and level of current needed to achieve the desired temperature for each corresponding location on the build plate and the system electronically communicates the polarity bias and current to the controller for each thermoelectric cell associated with the corresponding location. When the correct temperature gradient is achieved, printing is initiated 160. The system monitors the temperature of the build plate as each layer of printing is completed and electronically communicates the polarity bias and current level needed to the thermal controller for each thermoelectric cell to adjust the temperature to maintain the temperature profile of the build plate 162.

During the build process, the system dynamically monitors the electronic and thermal performance of the system and compares the performance data to a set of predetermined parameters 164, and communicates electronically to the printer and printer operator 166 if the build process should halt or if any remedial action may be taken to prevent a process failure and to protect the safety of the operator, the printer, and the surrounding environment.

During the build phase, if the temperature of the build plate at a location proximate to a particular temperature sensor 14 is not within the range of a predetermined temperature threshold, then the respective thermal controller determines that it may be necessary to energize the thermoelectric cells 12 associated with the respective temperature sensor 14 with the appropriately biased electric current to heat or cool the location on the build platform 10 proximate to the associated temperature sensor 14.

When the printer has completed building the intended part, the system initiates the cooling process. The compares the temperature at each polling location on the build plate and compares the temperatures to the target values in the file corresponding to each polled location on the build plate 170. An algorithm calculates the polarity bias and level of current needed for each thermoelectric cell to cool the build plate in accordance with the cool down temperature gradient of the build plate. The system communicates the polarity bias and the current values to the controllers for each thermoelectric cell. 172 The system sequentially polls each mapped location of the build platform corresponding to each respective thermoelectric cell 174. The system repeats the procedure for the entire surface of the build plate and may compare the thermal gradient at each point to the thermal profile for the specific build process 174. The system continues to loop through the cooling process until the temperature of the build plate matches the thermal gradient calculated at the start of the cooling process and until the finished part releases from the build plate and the process ends 176.

1. A system for controlling the temperature of a build plate for a three-dimensional printer comprised of:
a build platform having a first planar surface and a second planar surface on the opposite side of the first surface of the build platform;
a plurality of thermoelectric cells attached to the second surface of the build platform and in electronic communication with a temperature controller;
at least one temperature sensor connected to the build platform and in electronic communication with a temperature controller;
a thermal conduction apparatus physically connected to the thermoelectric cells; and
a temperature controller having means for accepting electronic temperature signals from the temperature sensors, processing the temperature signals and transmitting signals to the thermoelectric cells to control the temperature of the build platform.

2. The system of claim 1 wherein the build platform is a substantially rigid planar material adapted to fit horizontally within and across the bottom of the build chamber of a three-dimensional printer comprised of:
a build plate providing a first planar surface adapted to support a work-in-process and a second planar surface on the opposite side of the build plate from the first surface upon which an electronic circuit is provided.

3. The system of claim 2 wherein the electronic circuit is etched directly onto the second planar surface of the build plate.

4. The system of claim 2 wherein the plurality of temperature sensors are rigidly attached to the electronic circuit of the build platform and adapted to sense the temperature of the multifunctional build platform and electronically communicate the temperature through the electronic circuit to the temperature controller.

5. The system of claim 1 wherein the build platform is composed of a rigid thermally conductive material that remains dimensionally stable over the temperature range of the work-in-process output of a three dimensional printer that occurs within the build chamber of a three dimensional printer comprised of:
a first surface that supports a work-in-process during the build phase of a three-dimensional printer;
a second surface having an electronic circuit that provides electronic communication between temperature sensors and a thermal controller; and
wherein the at least one temperature sensor comprises a plurality of temperature sensors connected by solder or other means to the electronic circuit and adapted to sense the temperature of the build platform, convert the sensed temperature to an electronic signal and provide electronic communication between the plurality of temperature sensors and the thermal controller; and
wherein the plurality of thermoelectric cells comprises a plurality of thermoelectric cells securely attached to the electronic circuit of the second surface of the build platform and coupled proximately to the second surface of the build plate to efficiently heat and cool the build platform in response to appropriately biased electric current received from the thermal controller.

6. The system of claim 1, wherein the build platform is composed of a ceramic compound.

7. The system of claim 1 wherein each thermoelectric device is appropriately biased and powered by electric currents received from the electronic circuit on the second surface of the build platform to heat and cool the build platform.

8. The system of claim 1 wherein the thermal conduction apparatus is comprised of:
a base plate made of a rigid thermally conductive material;
a plurality of heat pipes connected to the base plate; and
a plurality of radiative elements made of thermally conductive material and connected to the heat pipes.

9. The system of claim 1 wherein the thermal conduction apparatus is comprised of:
at least one water block cooler connected to the thermoelectric cells and adapted to function with a liquid to transfer heat to and from the thermoelectric cells.

10. The system of claim 8 wherein the base plate is a rigid planar thermal conductor made of a metal such as copper or aluminum or any other substantially rigid thermally conductive material.

11. The system of claim 8 wherein each of the heat pipes in the plurality of heat pipes provides:
a first linear tubular element attached to the base plate; and
a second linear tubular element that is geometrically oriented to the first linear tubular element and physically connected to each radiative element in the plurality of radiative elements that are connected to the exterior of a build chamber for a three-dimensional printer.

12. The system of claim 8 wherein each of the radiative elements is an extended semi tubular element securely attached to the second linear tubular element of a heat pipe and the exterior frame of a three dimensional printer oriented orthogonally to the base plate of the thermal conductive apparatus.

13. The system of claim 8 wherein the temperature controller provides means for changing the temperature uniformly across the build plate in response to a predefined profile that corresponds to the thermal specifications for a work in process produced by the three-dimensional printer.

14. The system of claim 8 wherein the temperature controller provides means for changing the temperature in a variable gradient across the build plate in response to a predefined profile that corresponds to the thermal specifications for a work in process produced by the three-dimensional printer.

15. A system for controlling the temperature of a build plate for a three-dimensional printer comprised of:
a multifunctional build platform having a first planar surface and a second planar surface on the opposite side of the first surface of the multifunctional build platform in which the build platform is made from ceramic or other suitable material that provides:
a first surface that supports a work-in-process during the production cycle of a three dimensional printer;
a second surface on the opposite side of the build platform upon which a printed circuit is provided and that provides power from an external power supply and that transmits electronic signals to a temperature controller;
a plurality of thermoelectric cells, each thermoelectric cell in the plurality of cells attached to the second surface of the build platform and attached to the printed circuit on the second surface of the build platform;
a plurality of temperature sensors, each temperature sensor in the plurality of temperature sensors attached to the second surface of the build platform and the printed circuit and that sense the temperature of the build plate, convert the temperature readings to electronic signals, and transmit the electronic signals to the electric circuit;
a thermal conduction apparatus having:
a conductive base plate made of a rigid thermally conductive material having a first planar surface attached to the thermoelectric cells of and a second planar surface on the opposite side of the base plate from the first planar surface;
a plurality of heat pipes, each heat pipe in the plurality of heat pipes having a first element attached to the second surface of the base plate and a second element connected to extended radiative elements that are attached to the exterior of a three-dimensional printer;
a plurality of extended radiative elements, each radiative element in the plurality of radiative elements made of a rigid thermally conductive material and having an inner surface attached to a second element of a heat pipe and the outer frame of a three-dimensional printer; and
a temperature controller having means for accepting electronic temperature signals from the temperature sensors, processing the temperature signals and transmitting current to the thermoelectric cells to control the temperature across the build platform.

16. The system of claim 15 wherein the temperature controller comprises:
a module programmed to receive a temperature profile for work-in-process product;
a module programmed to receive signals communicated from the temperature sensors while the three-dimensional printer produces a work-in-process; and
a module programmed to transmit appropriately biased electric current to the thermoelectric cells at the end of the build cycle.

17. The system of claim 15 wherein the temperature controller comprises:
a control module programmed to receive a temperature profile for work-in-process product;
an input module programmed to receive signals communicated from the temperature sensors while the three-dimensional printer produces a work-in-process; and
an output module programmed to transmit appropriately biased electric current to the thermoelectric cells.

18. The system of claim 15 wherein the temperature controller comprises:
a control module programmed to receive a temperature profile for work-in-process product;
an input module programmed to receive signals communicated from the temperature sensors while the three-dimensional printer produces a work-in-process; and
a processing module that determines the temperature gradient across the surface of an output module programmed to transmit appropriately biased electric current to each thermoelectric cells.

19. A system for controlling the temperature of a build plate for a three-dimensional printer comprised of:
a multifunctional build platform having a first planar surface and a second planar surface on the opposite side of the first surface of the multifunctional build platform in which the build platform is made from ceramic or other suitable material that provides:
a first surface that supports a work-in-process during the production cycle of a three dimensional printer; and
a second surface on the opposite side of the build platform upon which a printed circuit is etched or bonded to that provides power from an external power supply and that transmits electronic signals;
at least one water block attached to the second surface of the build platform;
a plurality of temperature sensors that are attached to the second surface of the build platform and the printed circuit and that sense the temperature of the build plate, convert the temperature readings to electronic signals, and transmit the electronic signals to the electric circuit; and
a temperature controller having means for accepting electronic temperature signals from the temperature sensors, processing the temperature signals and transmitting signals to the water blocks to control the temperature in accordance with a pre-defined gradient across the build platform.

20. An apparatus for conducting heat to and from a build plate for a three-dimensional printer comprised of:
a plurality of thermoelectric cells, each thermoelectric cell in the plurality of thermoelectric cells attached to the build plate and in electronic communication with a temperature controller;
at least one temperature sensor connected to the build platform and in electronic communication with a temperature controller;
an electronic circuit attached to the thermoelectric cells and the temperature sensors and adapted to provide current to the thermoelectric cells and electronic communication between the temperature sensors and a temperature controller;
a thermal conductor physically connected to the thermoelectric cells; and
a temperature controller having means for accepting electronic temperature signals from the temperature sensors, processing the temperature signals and transmitting current to the thermoelectric cells to control the temperature of the build platform.
